(19) United States
(12) Patent Application Publication
(10) Pub. No.: US 2024/0387305 A1
(43) Pub. Date: Nov. 21, 2024

(54) SEMICONDUCTOR PACKAGE HAVING A DIE PAD AND AN ENCAPSULATION WITH TRENCHES AND METHOD FOR FABRICATING THE SAME

(71) Applicant: Infineon Technologies AG, Neubiberg (DE)

(72) Inventors: Meng How Chong, Paya Rumput (MY); Muhammad Safie Rosli, Durian Tunggal (MY); Michael Reyes Godoy, Melaka (MY); Ke Yan Tean, Paya Rumput (MY)

(21) Appl. No.: 18/647,712

(22) Filed: Apr. 26, 2024

(30) Foreign Application Priority Data
May 15, 2023 (DE) 102023204525.7

(51) Int. Cl. H01L 23/29; H01L 21/48; H01L 21/56; H01L 23/31; H01L 23/495

(52) U.S. Cl. CPC H01L 23/295; H01L 21/4828; H01L 21/4842; H01L 21/565; H01L 23/3121; H01L 23/49503; H01L 23/49548; H01L 23/49586

(57) ABSTRACT

A semiconductor package includes: a die pad having opposing first and second sides and lateral sides connecting the first and second sides; at least one semiconductor die arranged over the first side; an encapsulation including a first dielectric material and encapsulating the semiconductor die, the second side of the die pad being at least partially exposed from the encapsulation; and a contiguous isolation structure including a second dielectric material different from the first dielectric material and covering the second side of the die pad. The encapsulation includes at least one first trench arranged along at least a part of a contour of the second side of the die pad. The second side of the die pad includes at least one second trench arranged along at least a part of the contour of the second side of the die pad. The trenches are filled by the contiguous isolation structure.

### TECHNICAL FIELD

This disclosure relates in general to a semiconductor package, in particular a semiconductor package comprising a die pad and an encapsulation with trenches, as well as to a method for fabricating such a semiconductor package.

### BACKGROUND

A semiconductor package may comprise a die pad, a semiconductor die arranged over a first side of the die pad and an encapsulation encapsulating the semiconductor die. A second side of the die pad, opposite the first side, may be configured to be thermally coupled to a heatsink in order to dissipate heat generated by the semiconductor die during operation. The semiconductor die may be electrically coupled to the die pad and it may be desirable to electrically isolate the die pad from the heatsink. The dielectric material of the encapsulation may not be ideally suited for this task and therefore a different dielectric material may be arranged over the second side of the die pad. However, due to differences in the coefficient of thermal expansion between the die pad, the material of the encapsulation and the further dielectric material, tears or other defects may occur, for example in the further dielectric material. Such defects may for example negate the electrical isolation between the die pad and the heatsink. Improved semiconductor packages and improved methods for fabricating semiconductor packages may help in solving these and other problems.

### SUMMARY

Various aspects pertain to a semiconductor package, comprising: a die pad comprising a first side, an opposite second side and lateral sides connecting the first and second sides; at least one semiconductor die arranged over the first side of the die pad; an encapsulation comprising a first dielectric material and encapsulating the at least one semiconductor die, wherein the second side of the die pad is at least partially exposed from the encapsulation; and a contiguous isolation structure comprising a second dielectric material different from the first dielectric material and covering the second side of the die pad, wherein the encapsulation comprises at least one first trench arranged along at least a part of a contour of the second side of the die pad, wherein the second side of the die pad comprises at least one second trench arranged along at least a part of the contour of the second side of the die pad, and wherein the first and second trenches are filled by the contiguous isolation structure.

Various aspects pertain to a method for fabricating a semiconductor package, the method comprising: providing a die pad comprising a first side, an opposite second side and lateral sides connecting the first and second sides, arranging at least one semiconductor die over the first side of the die pad, encapsulating the at least one semiconductor die with an encapsulation comprising a first dielectric material such that the second side of the die pad is at least partially exposed from the encapsulation, covering the second side of the die pad with a contiguous isolation structure comprising a second dielectric material different from the first dielectric material, providing in the encapsulation at least one first trench arranged along at least a part of a contour of the second side of the die pad, providing in the second side of the die pad at least one second trench arranged along at least a part of the contour of the second side of the die pad, and filling the first and second trenches with the contiguous isolation structure.

### BRIEF DESCRIPTION OF THE DRAWINGS

The accompanying drawings illustrate examples and together with the description serve to explain principles of the disclosure. Other examples and many of the intended advantages of the disclosure will be readily appreciated in view of the following detailed description. The elements of the drawings are not necessarily to scale relative to each other. Identical reference numerals designate corresponding similar parts.

FIGS. 1A and 1B show a sectional view (FIG. 1A) and a plan view (FIG. 1B) of a semiconductor package, wherein a die pad and an encapsulation each comprise a trench.

FIGS. 2A to 2D show detail views of trenches in a die pad and in an encapsulation, according to different examples of a semiconductor package.

FIG. 3 shows a plan view of a further semiconductor package, wherein trenches in the die pad and in the encapsulation are interrupted.

FIG. 4 is a flow chart of an exemplary method for fabricating a semiconductor package, wherein a die pad and an encapsulation each comprise a trench.

### DETAILED DESCRIPTION

In the following detailed description, reference is made to the accompanying drawings. It may be evident, however, to one skilled in the art that one or more aspects of the disclosure may be practiced with a lesser degree of the specific details. In other instances, known structures and elements are shown in schematic form in order to facilitate describing one or more aspects of the disclosure. In this regard, directional terminology, such as “top”, “bottom”, “left”, “right”, “upper”, “lower” etc., is used with reference to the orientation of the Figure(s) being described. Because components of the disclosure can be positioned in a number of different orientations, the directional terminology is used for purposes of illustration only. It is to be understood that other examples may be utilized and structural or logical changes may be made.

In addition, while a particular feature or aspect of an example may be disclosed with respect to only one of several implementations, such feature or aspect may be combined with one or more other features or aspects of the other implementations as may be desired and advantageous for any given or particular application, unless specifically noted otherwise or unless technically restricted. Furthermore, to the extent that the terms “include”, “have”, “with” or other variants thereof are used in either the detailed description or the claims, such terms are intended to be inclusive in a manner similar to the term “comprise”. The terms “coupled” and “connected”, along with derivatives thereof may be used. It should be understood that these terms may be used to indicate that two elements cooperate or interact with each other regardless of whether they are in direct physical or electrical contact, or they are not in direct contact with each other; intervening elements or layers may be provided between the “bonded”, “attached”, or “connected” elements. However, it is also possible that the “bonded”, “attached”, or “connected” elements are in direct contact with each other. Also, the term “exemplary” is merely meant as an example, rather than the best or optimal.

The semiconductor die(s) of the semiconductor packages described below may be manufactured from specific semiconductor material, for example Si, SiC, SiGe, GaAs, GaN, or from any other suitable semiconductor material, and, furthermore, may contain one or more of inorganic and organic materials that are not semiconductors, such as for example insulators, plastics or metals.

The semiconductor packages described below may include one or more semiconductor dies. By way of example, one or more power semiconductor power dies may be included. Further, one or more logic integrated circuits may be included in the semiconductor packages. The logic integrated circuits may be configured to control the integrated circuits of other semiconductor dies, for example the integrated circuits of power semiconductor dies. The logic integrated circuits may be implemented in logic dies.

An efficient semiconductor package as well as an efficient method for fabricating a semiconductor package may for example reduce material consumption, ohmic losses, chemical waste, etc. and may thus enable energy and/or resource savings. Improved semiconductor packages as well as improved methods for fabricating a semiconductor package, as specified in this description, may thus at least indirectly contribute to green technology solutions, i.e. climate-friendly solutions providing a mitigation of energy and/or resource use.

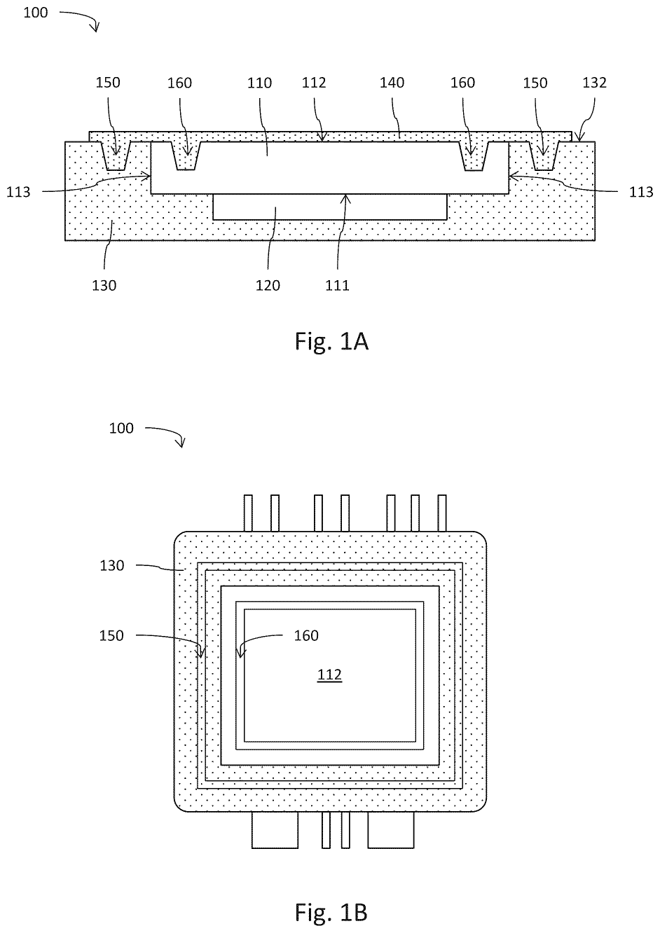

FIGS. 1A and 1B show a semiconductor package 100 comprising a die pad 110, at least one semiconductor die 120, an encapsulation 130 and an isolation structure 140. Furthermore, at least one first trench 150 is arranged in the die pad 110 and at least one second trench 160 is arranged in the encapsulation 130. FIG. 1A shows a sectional view and FIG. 1B shows a plan view, wherein the isolation structure 140 is omitted in FIG. 1B in order to show the trenches 150 and 160.

The semiconductor package 100 may for example be a power semiconductor package configured to operate with a high electrical current and/or a high voltage. The semiconductor package 100 may comprise or be part of any suitable electrical circuitry, e.g. a converter circuit, an inverter circuit, a half bridge circuit, a full bridge circuit, etc.

The die pad 110 comprises a first side 111, an opposite second side 112 and lateral sides 113 connecting the first and second sides 111, 112. The die pad 110 may have any suitable shape and any suitable dimensions. For example, the die pad 110 may have an essentially rectangular shape or an essentially quadratic shape as viewed from above the second side 112.

The die pad 110 may have any suitable thickness measured between the first and second sides 111, 112, for example a thickness in the range of about 0.4 mm to about 1 cm. The lower limit of this range may also be about 0.6 mm, 0.8 mm, 1 mm, 1.2 mm, 1.5 mm, 2 mm, or 3 mm and the upper limit may also be about 8 mm, 6 mm, or 4 mm. The die pad 110 may for example have a length and/or a width measured between opposite lateral sides 113 in the range of about 5 mm to about 20 cm. The lower limit of this range may also be about 1 cm, 2 cm, or 5 cm and the upper limit may also be about 15 cm, 10 cm, or 8 cm.

The die pad 110 may comprise or consist of any suitable material, in particular any suitable metal or metal alloy. For example, the die pad 110 may comprise or consist of Ag, Al, or Cu. According to an example, the die pad 110 is a leadframe part.

The at least one semiconductor die 120 is arranged over the first side 111 of the die pad 110. The semiconductor package 100 may comprise any suitable number of semiconductor dies 120, e.g. one, two, three, four, etc. Two or more semiconductor dies 120 may be arranged over the same die pad 110. However, it is also possible that the semiconductor package 100 comprises more than one die pad 110 which may for example be arranged laterally next to each other and at least one semiconductor die 120 is arranged over a further one of the die pads 110. The more than one semiconductor dies 120 may all be identical dies or different types of semiconductor dies.

According to an example, the semiconductor die 120 comprises a first power terminal (e.g. a drain, source, emitter or collector terminal) arranged on a first side, wherein the first side faces the first side 111 of the die pad 110. The first power terminal may be coupled to the die pad by, for example, a solder joint, a sintered joint, or a joint comprising conductive glue. The semiconductor die 120 may also comprise a second power terminal (e.g. a drain, source, emitter or collector terminal) arranged on a second side, opposite the first side. The semiconductor die 120 may further comprise a control terminal, e.g. a gate terminal, which may for example be arranged on the second side. The semiconductor die 120 may for example be a die of the type MOSFET (metal-oxide-semiconductor field-effect transistor) or HEMT (high-electron-mobility transistor) or IGBT (insulated-gate bipolar transistor).

The encapsulation 130 comprises a first dielectric material and encapsulates the at least one semiconductor die 120. The encapsulation also partially encapsulates the die pad 110 such that the second side 112 of the die pad 110 is at least partially exposed from the encapsulation 130.

The first dielectric material of the encapsulation 130 may be any suitable dielectric material configured to protect the semiconductor die 120 and/or to provide electrical isolation between particular components of the semiconductor package 100. The first dielectric material may for example comprise a mold compound. The first dielectric material may be epoxy based. The first dielectric material (and therefore, the encapsulation 130) may be essentially solid after curing.

According to an example, the first dielectric material may comprise silica (SiO₂) based filler particles. The filler particles may for example be configured to reduce the thermal resistance of the encapsulation 130. The first dielectric material may comprise any suitable amount of the filler particles, for example the filler particles may constitute 30 vol % or more of the encapsulation 130, or 50 vol % or more, or 70 vol % or more.

The encapsulation 130 may for example be fabricated using a suitable molding process, e.g. a process comprising compression molding, injection molding or transfer molding.

The isolation structure 140 comprises a second dielectric material different from the first dielectric material. The second dielectric material may for example be epoxy based. The second dielectric material may comprise alumina (Al₂O₃) based filler particles which may for example be configured to reduce the thermal resistance of the isolation structure 140. The second dielectric material may comprise any suitable amount of the filler particles, for example the filler particles may constitute 30 vol % or more of the isolation structure 140, or 50 vol % or more, or 70 vol % or more.

According to an example, the second dielectric material is essentially fluid or viscous or at least less rigid or more ductile than the first dielectric material after curing.

The isolation structure 140 covers the second side 112 of the die pad 110. In particular, the isolation structure 140 may completely cover the part of the second side 112 of the die pad 110 that is exposed from the encapsulation 130 (in the example shown in FIG. 1A, the whole second side 112 is exposed from the encapsulation 130).

The isolation structure 140 may be configured to electrically isolate the die pad 110 from an external part, e.g. a heatsink, which may be arranged over the second side 112 of the die pad 110. The isolation structure 140 may essentially have the shape of a comparatively thin layer covering the second side 112 of the die pad and at least part of a second side 132 of the encapsulation 130.

The isolation structure 140 may be deposited on the second side 112 of the die pad 110 using any suitable process. For example, the isolation structure 140 (or a precursor of the isolation structure 140) may be dispensed onto the second side 112 in fluid form or the isolation structure 140 may be deposited by picking-and-placing a preform having the form of a sheet.

The encapsulation 130 (in particular, the second side 132 of the encapsulation 130) comprises at least one first trench 150 arranged along at least a part of a contour of the second side 112 of the die pad 110. Furthermore, the second side 112 of the die pad 110 comprises at least one second trench 160 arranged along at least a part of the contour of the second side 112 of the die pad 110.

According to an example, the first and second trenches 150, 160 are arranged equidistant from the contour of the die pad 110 within a margin of no more than 50 μm, in particular within a margin of no more than 20 μm. According to an example, a distance of the first trench 150 and/or a distance of the second trench 160 from the contour of the second side 112 of the die pad 110 is in a range of 50% to 500% of the depth of the first and/or the second trench 150, 160, in particular in a range of 70% to 150% of the depth.

As shown in FIG. 1A, the first and second trenches 150, 160 are filled by the isolation structure 140. The isolation structure 140 which fills the first and second trenches 150, 160 is contiguous, meaning that the part of the isolation structure 140 which fills the first trench 150 is connected with the part which fills the second trench 160. According to the example shown in FIG. 1A, the isolation structure 140 is a single piece such that all parts are connected.

The first trench 150 may for example enhance the adhesion of the isolation structure 140 to the encapsulation 130. However, the encapsulation 130 on the one hand and the die pad 110 on the other hand may exhibit a difference in the coefficient of thermal expansion. Due to this difference, a strong pulling force may be exerted onto the isolation structure 140 by the first trench 150. This could result in a tear in the isolation structure 140 above the second side 112 of the die pad 110, damaging the electrical isolation of the die pad 110 which the isolation structure 140 provides. The second trench 160 arranged in the die pad 110 however may be configured to counteract this pulling force of the first trench 150 and may thereby prevent such a tear in the isolation structure 140 from forming.

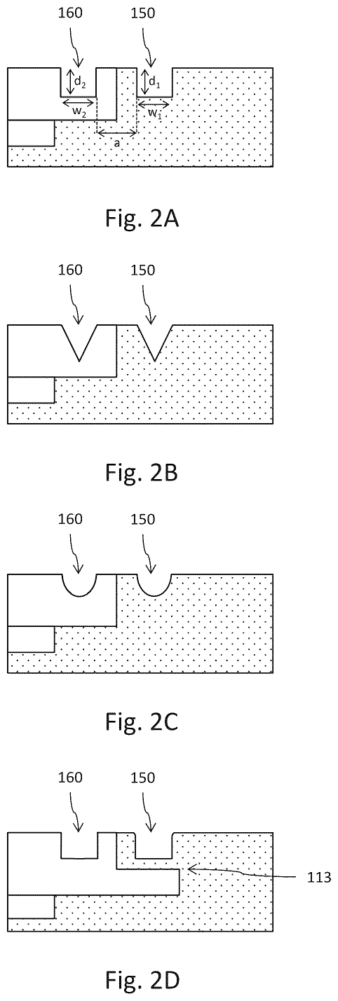

FIGS. 2A to 2D show detail views of the first and second trenches 150, 160, according to different examples of a semiconductor package 100.

As shown in FIG. 2A, the first and second trenches may have an essentially rectangular cross section. The trenches 150, 160 may also for example have a trapezoidal shape as shown in FIG. 1A.

According to an example, the first trench 150 has a depth d₁ in the range of 0.1 mm to 0.5 mm, in particular in the range of 0.18 mm to 0.22 mm. According to an example, the first trench 150 has a width w₁ in the range of 0.1 mm to 0.5 mm, in particular in the range of 0.2 mm to 0.24 mm. According to an example, the second trench 160 has a depth de which is in the above mentioned range of d₁ and/or a width w₂ which is in the above mentioned range of w₁.

According to an example, a distance a between the first and second trenches 150, 160 may be in the range of 0.1 mm to 1 mm, in particular in the range of 0.2 mm to 0.8 mm or 0.3 mm to 0.6 mm.

Parts of identical lengths of the first and second trenches 150, 160 may have identical volumes within a margin of no more than 50%, in particular within a margin of no more than 30% or no more than 10%. In particular, the first and second trenches 150, 160 may have the same depth and/or the same width and/or the trenches 150, 160 may be arranged equidistantly from the contour of the die pad 110. This may ensure that the first and second trenches 150, 160 exert the same amount of pulling force onto the isolation structure 140.

As shown in FIG. 2B, the trenches 150, 160 may have an essentially triangular cross section and as shown in FIG. 2C, the trenches 150, 160 may also for example have an essentially circular or oval cross section. It should be noted that the trenches 150, 160 may have any suitable cross section. The trenches shown in FIGS. 2B and 2C may for example have the same depth and/or the same width and/or the same distance as disclosed with respect to FIG. 2A.

As shown in FIGS. 2A-2D, the first trench 150 and the second trench 160 may have identical cross sections. It is however also possible that the first and second trenches 150, 160 have different cross sections as long as the second trench 160 is configured to cancel out the pulling force exerted onto the isolation structure 140 by the first trench 150 (for example, because the cross sections of the first and second trenches 150, 160 have essentially the same surface area).

In the example shown in FIG. 2D, the lateral sides 113 of the die pad 110 comprise a step. In this case, the at least one first trench 150 may be arranged (directly) above the step. It is however also possible that the first trench 150 is arranged laterally next to the step.

The first and second trenches 150, 160 may be fabricated using any suitable process. For example, the first and/or the second trench 150, 160 may be fabricated by punching, cutting, milling or etching. The first trench 150 may also be fabricated by molding with a molding tool which comprises a properly shaped ridge to form the first trench 150. According to an example, the first and second trenches 150, 160 are fabricated in the same process and/or using the same equipment. According to another example, the trenches 150, 160 are fabricated in different processes.

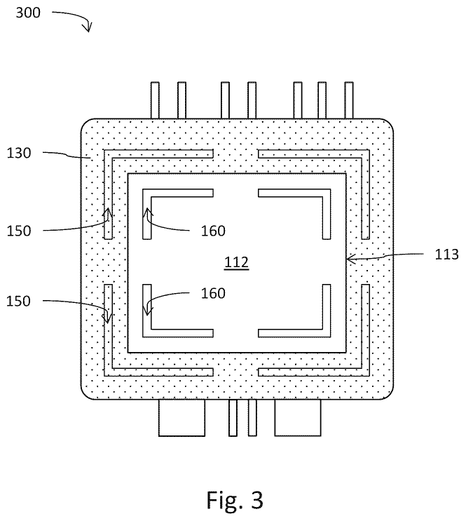

FIG. 3 shows a plan view of a semiconductor package 300 which may be similar or identical to the semiconductor package 100, except for the differences described in the following. In FIG. 3, the isolation structure 140 is omitted in order to show the trenches 150, 160.

As shown in FIG. 3, the first trench 150 and the second trench 160 of the semiconductor package 300 do not extend along the whole length of the contour of the second side 112 of the die pad 110. It is also possible that either the first trench 150 or the second trench 160 extends along only part of the contour and the other one of the trenches 150, 160 extends along the whole of the contour (as long as the trenches 150, 160 are configured such that no tear in the isolation structure 140 is created by a pulling force of the first trench 150).

According to an example, the first trench 150 and/or the second trench 160 is arranged along 50% or more, in particular along 60% or more, or 70% or more, or 80% or more, of the contour of the second side 112 of the die pad 110. According to an example, the overall length of the discontinuous first trench 150 and the discontinuous second trench 160 may essentially be identical.

The example shown in FIG. 3 comprises one discontinuity in the trenches 150, 160 at each lateral side 113 of the die pad 110. The trenches 150, 160 may of course comprise any suitable number of such discontinuities, for example two, three, four, etc. on each of the lateral sides 113 and the discontinuities may be arranged in any suitable pattern.

In the examples shown so far, the encapsulation 130 comprises a single first trench 150 and the die pad 110 comprises a single second trench 160. It is of course also possible that the semiconductor package comprises more than one first trench 150 (e.g. an inner first trench and an outer first trench) and/or more than one second trench 160.

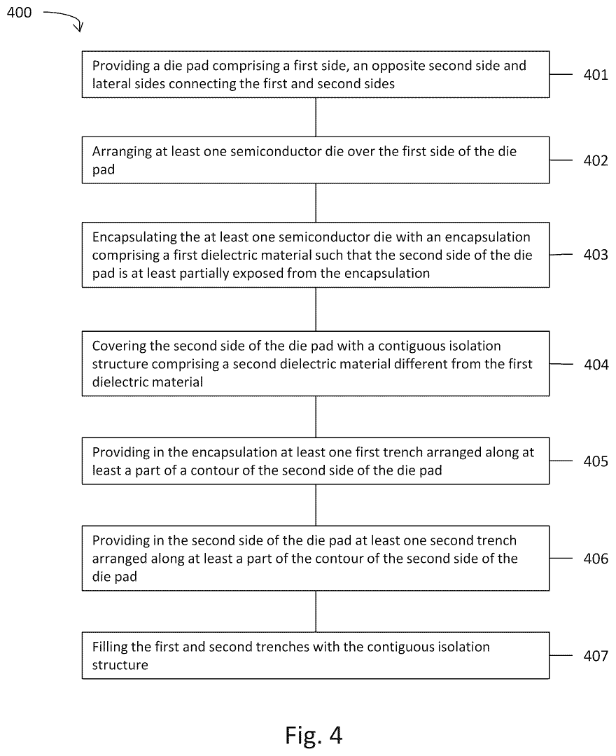

FIG. 4 is a flow chart of a method 400 for fabricating a semiconductor package. The method 400 may for example be used to fabricate the semiconductor package 100 or 300.

The method 400 comprises at 401 a process of providing a die pad comprising a first side, an opposite second side and lateral sides connecting the first and second sides; at 402 a process of arranging at least one semiconductor die over the first side of the die pad; at 403 a process of encapsulating the at least one semiconductor die with an encapsulation comprising a first dielectric material such that the second side of the die pad is at least partially exposed from the encapsulation; at 404 a process of covering the second side of the die pad with a contiguous isolation structure comprising a second dielectric material different from the first dielectric material; at 405 a process of providing in the encapsulation at least one first trench arranged along at least a part of a contour of the second side of the die pad; at 406 a process of providing in the second side of the die pad at least one second trench arranged along at least a part of the contour of the second side of the die pad; and at 407 a process of filling the first and second trenches with the contiguous isolation structure.

According to an example, the process 404 of covering the second side of the die pad with the contiguous isolation structure is performed after the processes 405 and 406 of providing the first and second trenches have been performed.

In the following, the semiconductor package and the method for fabricating a semiconductor package are further explained using specific examples.

Example 1 is a semiconductor package, comprising: a die pad comprising a first side, an opposite second side and lateral sides connecting the first and second sides, at least one semiconductor die arranged over the first side of the die pad, an encapsulation comprising a first dielectric material and encapsulating the at least one semiconductor die, wherein the second side of the die pad is at least partially exposed from the encapsulation, and a contiguous isolation structure comprising a second dielectric material different from the first dielectric material and covering the second side of the die pad, wherein the encapsulation comprises at least one first trench arranged along at least a part of a contour of the second side of the die pad, wherein the second side of the die pad comprises at least one second trench arranged along at least a part of the contour of the second side of the die pad, and wherein the first and second trenches are filled by the contiguous isolation structure.

Example 2 is the semiconductor package of example 1, wherein the first trench and/or the second trench is arranged along 50% or more of the contour of the second side of the die pad, in particular wherein the first and/or the second trench is arranged along 80% or more of the contour of the second side of the die pad.

Example 3 is the semiconductor package of example 1 or 2, wherein the first and second trenches are arranged equidistant from the contour within a margin of no more than 50 μm, in particular within a margin of no more than 20 μm.

Example 4 is the semiconductor package of one of the preceding examples, wherein parts of identical lengths of the first and second trenches have identical volumes within a margin of no more than 50%, in particular within a margin of no more than 30%.

Example 5 is the semiconductor package of one of the preceding examples, wherein the first and second trenches have identical cross sections.

Example 6 is the semiconductor package of one of the preceding examples, wherein the first and/or the second trench has a depth in the range of 0.1 mm to 0.5 mm, in particular in the range of 0.18 mm to 0.22 mm.

Example 7 is the semiconductor package of one of the preceding examples, wherein the first and/or the second trench has a width in the range of 0.1 mm to 0.5 mm, in particular in the range of 0.2 mm to 0.24 mm.

Example 8 is the semiconductor package of one of the preceding examples, wherein a distance of the first and/or the second trench from the contour of the second side of the die pad is in the range of 50% to 500% of the depth of the first and/or the second trench.

Example 9 is the semiconductor package of one of the preceding examples, wherein the lateral sides of the die pad comprise a step, and wherein the at least one first trench is arranged above the step.

Example 10 is the semiconductor package of one of the preceding examples, wherein the first dielectric material comprises silica based filler particles and wherein the second dielectric material comprises alumina based filler particles.

Example 11 is a method for fabricating a semiconductor package, the method comprising: providing a die pad comprising a first side, an opposite second side and lateral sides connecting the first and second sides, arranging at least one semiconductor die over the first side of the die pad, encapsulating the at least one semiconductor die with an encapsulation comprising a first dielectric material such that the second side of the die pad is at least partially exposed from the encapsulation, covering the second side of the die pad with a contiguous isolation structure comprising a second dielectric material different from the first dielectric material, providing in the encapsulation at least one first trench arranged along at least a part of a contour of the second side of the die pad, providing in the second side of the die pad at least one second trench arranged along at least a part of the contour of the second side of the die pad, and filling the first and second trenches with the contiguous isolation structure.

Example 12 is the method of example 11, wherein the second trench is fabricated by punching and/or etching the second side of the die pad.

Example 13 is an apparatus comprising means for performing the method according to example 11 or 12.

While the disclosure has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the disclosure.

The expression “and/or” should be interpreted to cover all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

What is claimed is:

1. A semiconductor package, comprising:
a die pad comprising a first side, an opposite second side, and lateral sides connecting the first and second sides;
at least one semiconductor die arranged over the first side of the die pad;
an encapsulation comprising a first dielectric material and encapsulating the at least one semiconductor die, wherein the second side of the die pad is at least partially exposed from the encapsulation; and
a contiguous isolation structure comprising a second dielectric material different from the first dielectric material and covering the second side of the die pad,
wherein the encapsulation comprises at least one first trench arranged along at least a part of a contour of the second side of the die pad,
wherein the second side of the die pad comprises at least one second trench arranged along at least a part of the contour of the second side of the die pad,
wherein the at least one first trench and the at least one second trench are filled by the contiguous isolation structure.

2. The semiconductor package of claim 1, wherein the at least one first trench and/or the at least one second trench is arranged along 50% or more of the contour of the second side of the die pad.

3. The semiconductor package of claim 2, wherein the at least one first trench and/or the at least one second trench is arranged along 80% or more of the contour of the second side of the die pad.

4. The semiconductor package of claim 1, wherein the at least one first trench and the at least one second trench are arranged equidistant from the contour within a margin of no more than 50 μm.

5. The semiconductor package of claim 4, wherein the at least one first trench and the at least one second trench are arranged equidistant from the contour within a margin of no more than 20 μm.

6. The semiconductor package of claim 1, wherein parts of identical lengths of the at least one first trench and the at least one second trench have identical volumes within a margin of no more than 50%.

7. The semiconductor package of claim 6, wherein the parts of identical lengths of the at least one first trench and the at least one second trench have identical volumes within a margin of no more than 30%.

8. The semiconductor package of claim 1, wherein the at least one first trench and the at least one second trench have identical cross sections.

9. The semiconductor package of claim 1, wherein the at least one first trench and/or the at least one second trench has a depth in a range of 0.1 mm to 0.5 mm.

10. The semiconductor package of claim 9, wherein the depth is in a range of 0.18 mm to 0.22 mm.

11. The semiconductor package of claim 1, wherein the at least one first trench and/or the at least one second trench has a width in a range of 0.1 mm to 0.5 mm.

12. The semiconductor package of claim 11, wherein the width is in a range of 0.2 mm to 0.24 mm.

13. The semiconductor package of claim 1, wherein a distance of the at least one first trench and/or the at least one second trench from the contour of the second side of the die pad is in a range of 50% to 500% of a depth of the at least one first trench and/or the at least one second trench.

14. The semiconductor package of claim 1, wherein the lateral sides of the die pad comprise a step, and wherein the at least one first trench is arranged above the step.

15. The semiconductor package of claim 1, wherein the first dielectric material comprises silica based filler particles, and wherein the second dielectric material comprises alumina based filler particles.

16. A method for fabricating a semiconductor package, the method comprising:
providing a die pad comprising a first side, an opposite second side, and lateral sides connecting the first and second sides;
arranging at least one semiconductor die over the first side of the die pad;
encapsulating the at least one semiconductor die with an encapsulation comprising a first dielectric material such that the second side of the die pad is at least partially exposed from the encapsulation;
covering the second side of the die pad with a contiguous isolation structure comprising a second dielectric material different from the first dielectric material;
providing, in the encapsulation, at least one first trench arranged along at least a part of a contour of the second side of the die pad;
providing, in the second side of the die pad, at least one second trench arranged along at least a part of the contour of the second side of the die pad; and
filling the at least one first trench and the at least one second trench with the contiguous isolation structure.

17. The method of claim 16, wherein the at least one second trench is fabricated by punching and/or etching the second side of the die pad.
